(19) United States
(12) Patent Application Publication
(10) Pub. No.: US 2007/0158807 A1
(43) Pub. Date: Jul. 12, 2007

(54) Edge interconnects for die stacking

(76) Inventors: Daoqiang Lu, Chandler, AZ (US); Wei Shi, Gilbert, AZ (US); Qing Zhou, Chandler, AZ (US); Jiangqi He, Gilbert, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/322,297

(22) Filed: Dec. 29, 2005

(51) Int. Cl. H01L 23/02

(52) U.S. Cl. 257/686

(57) ABSTRACT

Electronic devices and methods for fabricating electronic devices are described. One embodiment includes an electronic device having a first die, the first die having a top surface, a bottom surface, and a plurality of side surfaces. The first die also includes a plurality of metal pads on the top surface extending to an outer edge of the top surface, and a plurality of metal pads on the bottom surface extending to an outer edge of the bottom surface. The first die also includes a plurality of metal regions along the side surfaces, wherein each of the metal regions extends between one of the metal pads on the top surface and one of the metal pads on the bottom surface. Other embodiments are described and claimed.

### RELATED ART

Integrated circuits may be formed on semiconductor wafers made of materials such as silicon. The semiconductor wafers are processed to form various electronic devices thereon. The wafers are diced into semiconductor chips or dies, which may then be attached to a package substrate using a variety of known methods. For instance, bonding pads on the die may be electrically connected to bonding pads on the package substrate using wire bonding. The die and wire bonds may be encapsulated with a protective material such as a polymer. To increase the amount of circuitry in a package, without increasing its area, packages with stacked dies have been formed. Such stacked die packages may include two or more dies separated by spacers, or, in certain configurations, the dies are stacked in a zig zag fashion (only two sides of the die are used for wire bonding).

An example of a stacked die package is shown in FIG. 1. The stacked die package 10 includes a first die 12 positioned on a package substrate 14 with an adhesive layer 16. The first die 12 is electrically coupled to the package substrate 14 through wire bonds 18. A second die 22 is positioned on the first die 12, with a spacer 24 and adhesive layers 26 and 28 between the second die 22 and the first die 12. The second die is electrically coupled to the package substrate 14 through wire bonds 30. The package substrate 14 may include terminals such as solder bumps 34, for connecting the package to another device such as a board (not shown). The package 10 may also include an encapsulation material 36 such as a polymer, to stabilize and protect the components.

As electronic components are being scaled down in size, wire bonded structures present problems relating to the size of the package, due to the need to provide adequate area for forming the wire bond. Wire bonded structure also present problems relating to the height of the package, due to the need for spacers and the like to ensure adequate spacing between the layer for wire clearance.

### BRIEF DESCRIPTION OF THE DRAWINGS

Embodiments are described by way of example, with reference to the accompanying drawings, which are not drawn to scale, wherein:

FIG. 1 illustrates a cross-sectional view of a conventional stacked die package having two dies wire bonded to a package substrate;

FIGS. 2-12 illustrate operations during the processing of a wafer to form dies having edge interconnect metallization structures, in accordance with certain embodiments;

FIG. 13 illustrates coupling a die to a substrate, in accordance with certain embodiments;

FIG. 14 illustrates coupling a die to another die that is coupled to a substrate, in accordance with certain embodiments;

FIG. 15 illustrates a substrate with a stack of dies thereon, in accordance with certain embodiments;

FIG. 16 illustrates the substrate with a stack of dies of FIG. 15, further including an encapsulant, in accordance with certain embodiments;

FIG. 17 illustrates a top view layout of a stacked die structure including dies having different sizes, in accordance with certain embodiments;

FIG. 18 illustrates a die structure, in accordance with certain embodiments;

FIG. 19 illustrates a package structure including the die of FIG. 18,-accordance with certain embodiments;

FIG. 20 illustrates a flow chart illustrating certain operations in forming an electronic device, in accordance with certain embodiments; and

FIG. 21 illustrates an electronic system arrangement in which embodiments may find application.

### DETAILED DESCRIPTION

Certain embodiments relate to die structures including metal pads formed thereon and methods for forming such structures. In certain embodiments, the die structures are electrically coupled to a substrate without the use of wire bonds. Certain embodiments also relate to stacked die structures and methods for forming such structures.

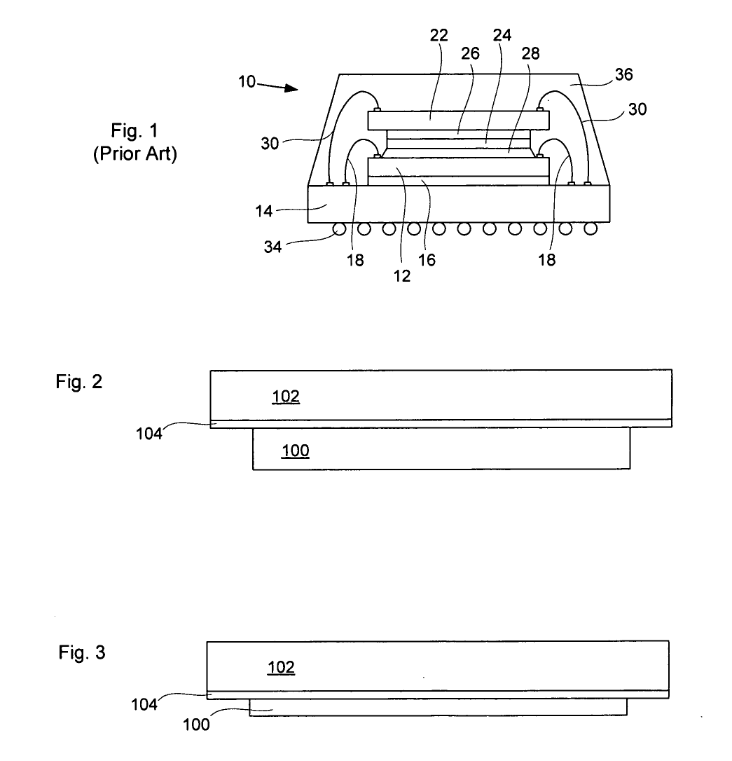

FIGS. 2-12 illustrate a process for forming a die structure having metal pads thereon, in accordance with certain embodiments. As illustrated in FIG. 2, a wafer 100 (from which a plurality of die structures may be formed) is coupled to a carrier 102 using an adhesive 104. As illustrated in FIG. 3, the wafer 100 may then be thinned to a desired thickness using any suitable method. For example, in certain embodiments, the wafer 100 is thinned to a thickness of 50-75 μm.

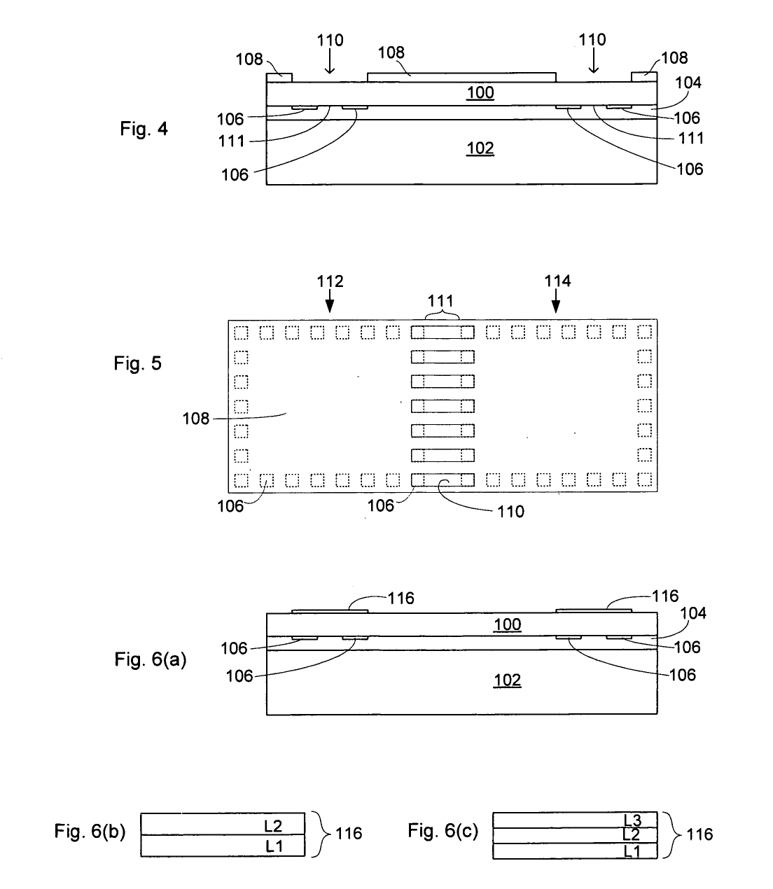

FIG. 4 illustrates a portion of the wafer 100 including a photoresist layer 108 deposited on the backside of the wafer 100 and openings 110 defined in the photoresist layer 108. The openings 110 are substantially aligned with respect to metal pads 106 formed on the front side of the wafer 100, so that, as seen in FIG. 4, the openings I 10 are aligned over at least a portion of the metal pads 106 and the street regions 111 between the metal pads 106. The front side of the wafer 100 refers to the bottom surface of the wafer 100 as illustrated in FIG. 4, which includes an active semiconductor region in which one or more devices (not shown) are formed, and the backside of the wafer 100 refers to the top surface of the wafer 100. In alternative embodiments, the backside surface or both surfaces may include active semiconductor regions.

FIG. 5 illustrates an elevated view of a portion of the wafer 100, showing two adjacent die regions 112 and 114 having the photoresist layer 108 thereon, including one group of the openings 110 in the photoresist layer 108 extending between the die region 112 and die region 114. As oriented in FIG. 5, the openings 110 are each aligned to be over at least a portion of one of the metal pads 106 (indicated by dotted lines in FIG. 5) of the first die region 112, aligned to be over at least a portion of one of the metal pads 106 of the second die region 114, and over the street region 111 between the first and second die regions 112, 114. The openings 110 in certain embodiments will be positioned over the metal pads 106 on all four side edges of each die region, and extend between the metal pad regions of the illustrated die regions 1 12, 114 and adjacent die regions (not shown).

As illustrated in FIG. 6(a), a layer 116, which may include one or more metal layers, is deposited in the openings 110 in the photoresist layer 108 on the wafer 100. Examples of the layer 112 are illustrated in FIGS. 6(b) and 6(c). FIG. 6(b) shows the layer 112 having two layers L1 and L2, for example, a Ti (titanium) layer and a Au (gold) layer. FIG. 6(c) shows the layer 112 having three layers L1, L2, and L3, for example, a Ti layer, a Ni (nickel) layer, and a Au layer.

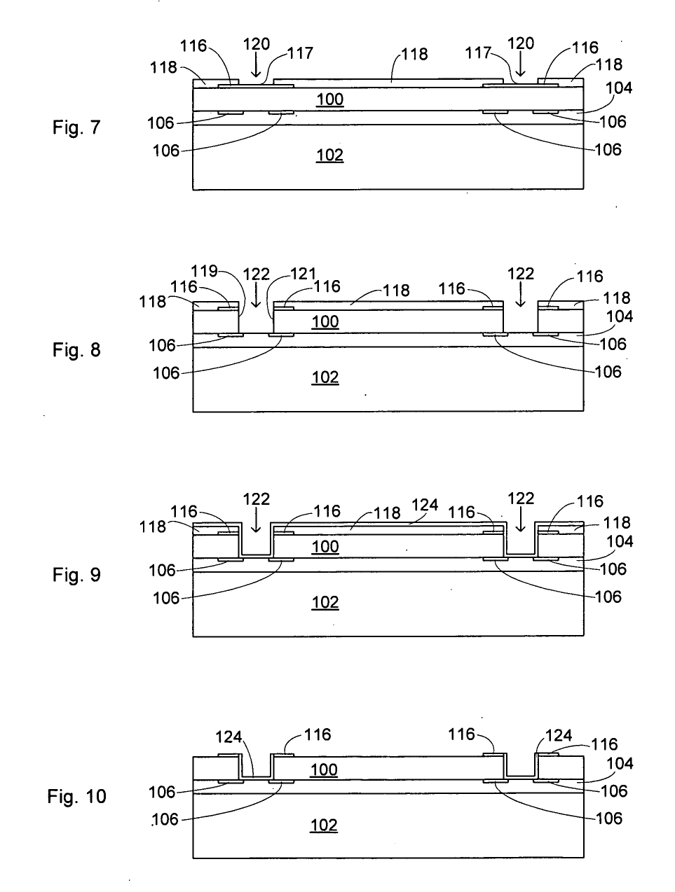

The photoresist layer 108 is then stripped off of the wafer 100 and another photoresist layer 118 is deposited on the backside of the wafer 100. As illustrated in FIG. 7, openings 120 are formed in the photoresist layer 118. The openings 120 extend through the photoresist layer 118 to a central portion 117 of the layer 116. End portions of the layer 116 are covered by the photoresist 118 on either side of the central portion 117.

As illustrated in FIG. 8, via holes 122 are etched through central portion 117 of the layer 116 and through the wafer 100, using the photoresist layer 118 as a mask. This forms two metal pads 116 (from the original layer 116) separated by a via hole 122. In certain embodiments, the etching may be carried out using a suitable dry-etching anisotropic deep silicon etch process, in which substantially vertical sidewalls may be achieved. The depth of the via holes 122 may be controlled so that the etching stops at the metal pads 106.

As illustrated in FIG. 9, a layer 124, which may include one or more metal layers, is formed in the via. In certain embodiments, a seed layer of Ti (titanium) or TiW (titanium tungsten) is first deposited using a suitable method such as sputtering, and then a layer of Au or layers of Ni and Au are plated thereon. The layer 124 may be formed in a manner so that the side surfaces 119, 121 of the wafer in the via 122 are covered by the layer 124 but the entire via 122 volume is not filled with the layer 124. The photoresist layer 118 may then be stripped off, as illustrated in FIG. 10, using a suitable method such as using an oxygen plasma.

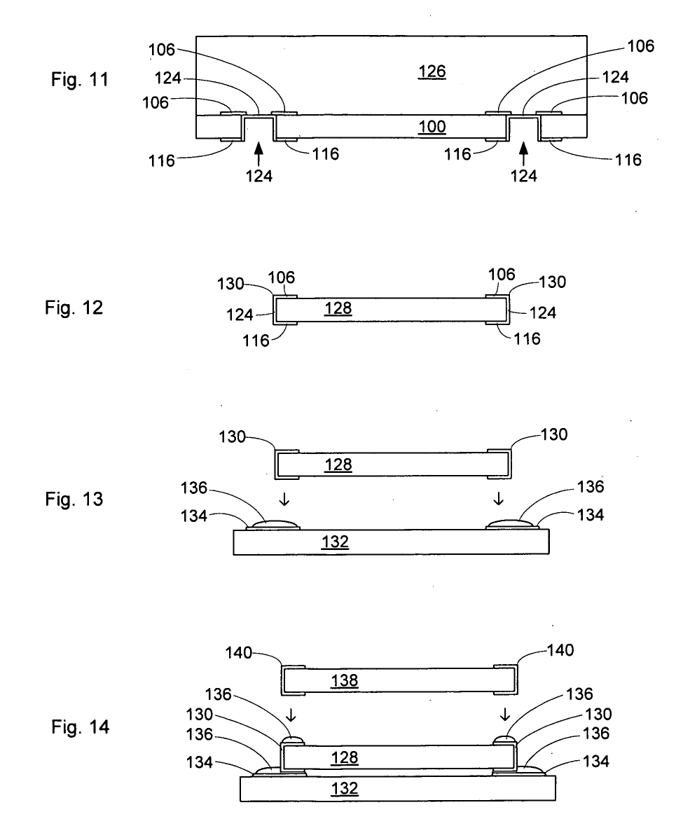

The wafer 100 may then be released from the carrier 102 and mounted on dicing tape 126, as illustrated in FIG. 11. The wafer 100 may then be diced between the adjacent die regions along lines defined by the vias 122 and removed from the dicing tape, to yield a plurality of dies such as die 128 illustrated in FIG. 12. The die 128 includes a plurality of edge interconnect metallizations 130, which include a metal pad 106 on the front side of the die 128, the interconnect layer 124 on the side surface of the die 128, and the metal pad 116 on the backside of the die 128.

As illustrated in FIG. 13, the die 128 may be positioned on a substrate 132. Wire bonds are not necessary to electrically couple the die 128 to the substrate 132. The substrate 132 may include pads 134 for electrical contact to the edge interconnect metallization 130 of the die 128. In certain embodiments a suitable bonding material 136 may be placed on the pads 134. Such a bonding material 136 includes, but is not limited to, an electrically conductive adhesive such as an epoxy with silver particles, or a solder.

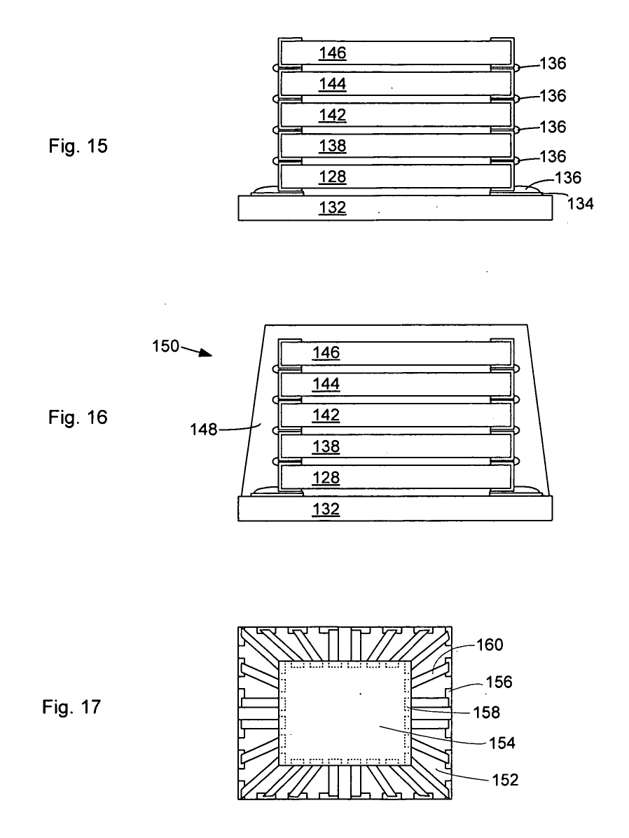

Multiple dies may be stacked on the substrate 132. Again, wire bonds are not necessary. As illustrated in FIG. 14, after the die 128 is in place on the substrate 132, another die 138 having a structure similar to that of die 128 (including edge interconnect metallizations 140 that are similar to the edge interconnect metallizations 130) is positioned over the die 128 and then brought into contact through another layer of the bonding material 136. The bonding material 136 is placed on the metal pad 116 of the interconnect metallization 130, which is positioned on the backside of the die 128. The die 138 is then placed on the bonding material 136 and stacked on the die 128. The process may be repeated to stack a plurality of additional dies 142, 144, and 146 on the stack, as illustrated in FIG. 15. Where a polymer bonding material has been used, such as an epoxy with metal particles, a curing operation is carried out, for example, at a temperature of about 150° C. for about 30 minutes to 1 hour, in air. An suitable encapsulant 148, such as a polymer, may also be used to seal and protect the stacked die package 150, as illustrated in FIG. 16.

A structure in accordance with certain embodiments such as the embodiment illustrated in FIG. 16 may include one or more of the following advantages over conventional structures. For example, a package substrate can have a smaller area because there is no need for additional area for attaching the wire bonds. Additionally, the height of each wire bond sometimes necessitates the use of a spacer to ensure adequate room for the wire between die layers. Embodiments such as that illustrated in FIG. 16 eliminate the need for such spacers and thus permit the die layers to be positioned substantially closer to each other, thus forming a more narrow package.

The stack illustrated in FIGS. 16 includes a plurality of dies 128, 138, 142, 144, 146 that are all formed to be substantially the same size. Embodiments also include dies having different sizes that are stacked together. For instance, FIG. 17 illustrates an embodiment in which first and second dies 152 and 154 are stacked, with the second die 154 having a smaller length and width than the first die 152. The first die edge interconnect metallizations 156 and the second die edge interconnect metallizations 158 may be formed in a similar manner as the edge interconnect metallizations 130 described above. An electrically conductive material 160 may be formed on the first die 152 to extend from the metal pads 156 on the top surface to positions that are coupled to a pad portion of the second die edge interconnect metallization 158 (indicated by dotted lines) on a bottom surface of the second die 154. In this manner, die structures of different sizes can be stacked together in the same package.

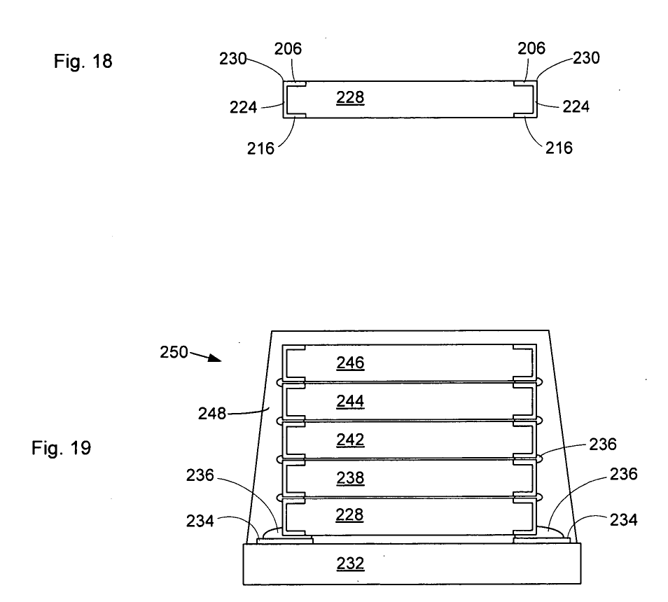

A variety of modifications may be made to the embodiments described above. For example, the die 128 as illustrated in FIG. 12 includes a plurality of edge interconnect metallization regions that include the metal pad 116 on the backside surface, interconnect layer 124 on a side edge, and metal pad 106 on the front side of the die 128. As illustrated in FIG. 12, the metal pad 116 extends outward from the rest of the backside surface of the die 128. Similarly, the metal pad 106 extends outward from the rest of the front side surface of the die 128. Thus, as shown in FIG. 12, the ends of the die 128 at the positions wherein the edge interconnect metallization 130 is formed have a thickness that is greater than the thickness where the metallization is not present. Other embodiments may be formed so that the edge interconnect metallization regions are flush with the rest of the die surface. In other words, the metal pads may each be formed in a recessed region on the die so that the surfaces will be substantially level with other portions of the die. FIG. 18 illustrates a die 228 formed to have such a structure, including metal pad 206 interconnect layer 224, and metal pad 216. Such a structure may be formed in a similar manner as the die 128 as described above. Additional photoresist patterning and etching steps may be carried out to form the recessed regions on the die 228 on which the metal pad 206 and metal pad 216 are formed.

A plurality of dies have a structure such as the die 228 in FIG. 18 may be stacked together to form a device 250 as illustrated in FIG. 19, with the dies 228, 238, 242, 244, and 246 being coupled to metal pads 234 on package substrate 232 using a bonding material 236. The dies 228, 238, 242, 244, and 246 may also be coupled together using the bonding material 236, which may include, but is not limited to, materials such as a polymer with metal particles therein, or a solder. An encapsulant layer 248 may also be used to seal and protect the device. Such a structure may permit a very thin package to be made due to the flat surfaces. For example, where an electrically conductive adhesive including metal particles therein is used as the bonding layer 236 material, the dies may be spaced apart by a distance that is related to the metal particle size.

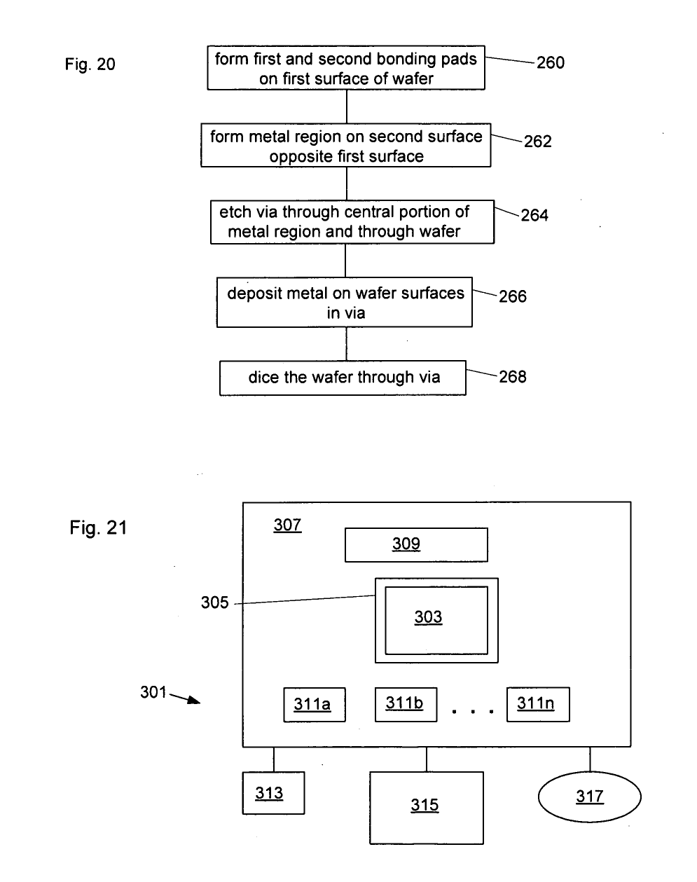

FIG. 20 is a flowchart describing a method in accordance with certain embodiments. Box 260 is forming first and second metal pads on a first surface of a wafer. The first and second bonding pads are positioned in adjacent die regions on the wafer. Box 262 is forming a metal region on a second surface of the wafer that is opposite the first surface. This may be carried out using a lithographic process to mask the second surface and form an opening the location where the metal is deposited. Box 264 is etching a via through the central portion of the metal region and through the wafer. The etching through the central portion of the metal region will divide the metal region into two separate metal pads on the second surface of the wafer, one being positioned in the first die region, the other being positioned in the second die region. The etching through the wafer forms side surfaces between the first and second surfaces of the wafer which extend to the first and second bonding pads on the first surface of the wafer and to the first and second metal pads on the second surface of the wafer. Box 266 is depositing metal on the side surfaces in the via, which electrically connects the first metal pad on the first surface with the first metal pad on the second surface, and which electrically connects the second metal pad on the first surface with the second bonding pad on the second surface. Box 268 is dicing the wafer through the via, which separates the first die from the second die.

Certain embodiments as described above may include packages for a variety of chip designs including, but not limited to, memory, controllers, processors, chipsets, ASIC's (application specific integrated circuits), and SOC's (system on a chip). FIG. 21 schematically illustrates one example of an electronic system environment in which aspects of described embodiments may be embodied. Other embodiments need not include all of the features specified in FIG. 21, and may include alternative features not specified in FIG. 21.

The system 301 of FIG. 21 may include at least one central processing unit (CPU) 303. The CPU 303, also referred to as a microprocessor, may be attached to an integrated circuit package 305, which is then coupled to a printed circuit board 307, which in this embodiment, may be a motherboard. The package 305 and CPU 303 is an example of an electronic device in the system 301 that may include a stacked die structure in accordance with embodiments such as described above, for example the structure illustrated in FIG. 16.

The system 301 further may further include memory 309 and one or more controllers 311a, 311b . . . 311n, which are also disposed on the motherboard 307. The memory 309 is another example of an electronic device in the system 301 that may include a stacked die structure in accordance with embodiments such as described above and illustrated, for example, in FIG. 16. The motherboard 307 may be a single layer or multi-layered board which has a plurality of conductive lines that provide communication between the circuits in the package 305 and other components mounted to the board 307. Alternatively, one or more of the CPU 303, memory 309 and controllers 311a, 311b . . . 311n may be disposed on other cards such as daughter cards or expansion cards. The CPU 303, memory 309 and controllers 311a, 311b . . . 311n may each be seated in individual sockets or may be connected directly to a printed circuit board. A display 315 may also be included.

Any suitable operating system and various applications execute on the CPU 303 and reside in the memory 309. The content residing in memory 309 may be cached in accordance with known caching techniques. Programs and data in memory 309 may be swapped into storage 313 as part of memory management operations. The system 301 may comprise any suitable computing device, including, but not limited to, a mainframe, server, personal computer, workstation, laptop, handheld computer, handheld gaming device, handheld entertainment device (for example, MP3 (moving picture experts group layer—3 audio) player), PDA (personal digital assistant) telephony device (wireless or wired), network appliance, virtualization device, storage controller, network controller, etc.

The controllers 311a, 311b . . . 311n may include a system controller, peripheral controller, memory controller, hub controller, I/O (input/output) bus controller, video controller, network controller, storage controller, communications controller, etc. For example, a storage controller can control the reading of data from and the writing of data to the storage 313 in accordance with a storage protocol layer. The storage protocol of the layer may be any of a number of known storage protocols. Data being written to or read from the storage 313 may be cached in accordance with known caching techniques. A network controller can include one or more protocol layers to send and receive network packets to and from remote devices over a network 317. The network 317 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. An electronic device comprising:
a first die having a top surface, a bottom surface, and a plurality of side surfaces;
a plurality of metal pads on the top surface extending to an outer edge of the top surface;
a plurality of metal pads on the bottom surface extending to an outer edge of the bottom surface; and
a plurality of metal regions along the side surfaces, wherein each of the metal regions extends between one of the metal pads on the top surface and one of the metal pads on the bottom surface.

2. The electronic device of claim 1, wherein each of the plurality of metal pads on the top surface extends outward from the top surface, and wherein each of the plurality of metal pads on the bottom surface extends outward from the bottom surface.

3. The electronic device of claim 1, further comprising a substrate having an upper surface facing the bottom surface of the first die, the substrate upper surface including a plurality of metal pads thereon, wherein the plurality of metal pads on the bottom surface of the die are coupled to the metal pads on the substrate upper surface through a bonding material.

4. The electronic device of claim 1, further comprising a second die including a bottom surface having a plurality of metal pads thereon, wherein the second die bottom surface metal pads are positioned in alignment with the plurality of metal pads on the top surface of first die, and wherein a plurality of the second die bottom surface metal pads are each coupled to one of the metal pads on the top surface of the first die through a bonding material.

5. The electronic device of claim 4, wherein the bonding material is selected from the group consisting of (i) a polymer with metal particles therein, and (ii) a solder.

6. The electronic device of claim 1, wherein the plurality of side surfaces includes four side surfaces.

7. The electronic device of claim 1, wherein the top surface includes a plurality of recessed regions into which the plurality of metal pads on the top surface are positioned, and wherein the bottom surface includes a plurality of recessed regions into which the plurality of metal pads on the bottom surface are positioned.

8. The electronic device of claim 1, wherein the metal pads include a plurality of layers.

9. The electronic device of claim 1, further comprising a second die,
the second die having a top surface, a bottom surface opposite the first surface, and a plurality of side surfaces; a plurality of metal pads on the top surface extending to an outer edge of the top surface; a plurality of metal pads on the bottom surface extending to an outer edge of the bottom surface; and a plurality of metal regions along the side surfaces, wherein each of the metal regions extends between one of the metal pads on the top surface and one of the metal pads on the bottom surface; and
wherein the second die is positioned on the first die so that the plurality of metal pads on the bottom surface of the second die are positioned directly over the plurality of metal pads on the top surface of the first die.

10. The electronic device of claim 9, wherein the second die is electrically coupled to the first die through a bonding material positioned between the first die and the second die.

11. The electronic device of claim 10, further comprising a plurality of additional dies stacked on the second die.

12. A system, comprising:
a microprocessor;
memory; and
a video controller;
wherein at least one of the microprocessor, the memory, and the video controller includes at least one electronic device comprising:
at least one die having a top surface, a bottom surface, and a plurality of side surfaces;
a plurality of metal pads on the top surface extending to an outer edge of the top surface;
a plurality of metal pads on the bottom surface extending to an outer edge of the bottom surface; and
a plurality of metal regions along the side surfaces, wherein each of the metal regions extends between one of the metal pads on the top surface and one of the metal pads on the bottom surface.

13. The system of claim 12, wherein the electronic device includes a plurality of the dies stacked together.

14. The system of claim 12, wherein the system further comprises a motherboard, and the device is coupled to the motherboard.

15. A method for forming an electronic device, comprising:
forming a plurality of metal pads extending to an outer edge of a first surface of a die;
forming a plurality of metal pads extending to an outer edge of a second surface of the die opposite the first surface; and
forming a plurality of interconnects on a plurality of side surfaces at a periphery of the die so that each of the interconnects is connected to one of the metal pads on the first surface and one of the metal pads on the second surface.

16. The method of claim 15, wherein the forming a plurality of metal pads extending to an outer edge of the die opposite the first surface comprises forming a plurality of metal regions extending over a portion of two adjacent die regions on a wafer, and etching a via through a central portion of each of the metal regions.

17. The method of claim 16, wherein the forming a plurality of interconnects on a plurality of side surfaces at a periphery of the die comprises etching the via through the wafer so that a side surface is formed at a periphery of the first die region and a side surface is formed at a periphery of the second die region, and then depositing a metal on the side surfaces.

18. The method of claim 17, further comprising aligning the metal region and the via so that the via extends through the wafer and contacts a portion of the metal pads on the first surface.

19. A method comprising:
forming first and second metal pads on a first surface of a wafer;
forming a metal region on a second surface opposite the first surface of the wafer;
etching the metal region and the wafer to form first and second metal pads on the second surface, and a via extending to the first and second metal pads on the first surface;
depositing a conductive material in the via to electrically interconnect the first metal pads on the first and second surfaces, and to electrically interconnect the second metal pads on the first and second surfaces; and
dicing the wafer through the via so that the first pads on the first and second surfaces remain electrically interconnected, and the second pads on the first and second surfaces remain electrically interconnected.

20. The method of claim 19, wherein the forming a metal region on a second surface opposite the first surface of the wafer includes forming a photoresist layer on the second surface, forming an opening in the photoresist layer that is aligned with at least a portion of the first and second metal pads on the first surface, and depositing a metal in the opening.

21. The method of claim 20, wherein the depositing a metal includes depositing a plurality of metal layers on the second surface in the opening.

22. The method of claim 21, wherein the etching the metal region and the wafer includes etching through a central portion of the metal region to form the first and second metal pads, and etching through the wafer includes forming sidewalls in the via, including a first sidewall positioned between the first pads on the first and second surfaces and a second sidewall positioned between the second pads on the first and second surfaces

23. The method of claim 22, wherein the depositing a conductive material in the via includes depositing at least two metal layers on the first sidewall and on the second sidewall.
